(19) United States
(12) Patent Application Publication
(10) Pub. No.: US 2021/0125095 A1
(43) Pub. Date: Apr. 29, 2021

(54) ANALYSIS METHOD AND ANALYSIS SYSTEM

(71) Applicant: Samsung Electronics Co., Ltd., Suwon-si (KR)

(72) Inventors: Rei SAKUMA, Tsurumi-ku (JP); Satoshi NAKAMURA, Tsurumi-ku (JP); Jaehyun BAE, Seoul (KR)

(73) Assignee: Samsung Electronics Co., Ltd., Suwon-si (KR)

(21) Appl. No.: 17/075,192

(22) Filed: Oct. 20, 2020

(30) Foreign Application Priority Data
Oct. 25, 2019 (JP) 2019-194370
Jul. 13, 2020 (KR) 10-2020-0085805

(51) Int. Cl. G06N 10/00; G06F 17/16; H03K 19/00

(52) U.S. Cl. CPC G06N 10/00; H03K 19/00; G06F 17/16

(57) ABSTRACT

Disclosed is an analysis method that calculates a Green's function while reducing the number of quantum gates required for calculation by a quantum processor. A classical processor converts a Hamiltonian operator of a sub-system corresponding to a basis function representing an ‘N±1’ electromagnetic field with respect to an analysis target substance having ‘N’ (where the ‘N’ is a natural number) number of electrons and an operator corresponding to an overlapping matrix of the basis function into a spin operator, and a quantum processor calculates an expected value of the spin operator. The classical processor calculates an element of a Hamiltonian matrix corresponding to the Hamiltonian operator and an element of the overlapping matrix, based on the expected value, and calculates a one-electron Green's function, based on the Hamiltonian matrix and the overlapping matrix.

### CROSS-REFERENCE TO RELATED APPLICATIONS

This application claims priority under 35 U.S.C. § 119 to Japan Patent Application No. 2019-194370 filed on Oct. 25, 2019, in the Japan Patent Office, and Korean Patent Application No. 10-2020-0085805 filed on Jul. 13, 2020, in the Korean Intellectual Property Office, the disclosures of which are incorporated by reference herein in their entireties.

### BACKGROUND

Example embodiments of the inventive concepts described herein relate to an analysis method and an analysis system, and more particularly, relate to an analysis method and an analysis system that analyzes an electronic state of a substance.

A technique for analyzing an electronic state of a substance by a quantum computer has been proposed. For example, Non-patent document 1, which is incorporated by reference herein in its entirety, discloses a method of calculating the electronic state based on a Green's function using the quantum computer have been researched. The methods may obtain the Green's function based a frequency by calculating a time-based Green's function and Fourier transforming the time-based Green's function. For example, Non-patent document 2, which is incorporated by reference herein in its entirety, discloses a technique for calculating the Green's function using the quantum computer.

However, methods, like the method disclosed in Non-patent document 1, often use a Trotter decomposition for discretization in the quantum algorithm, which requires a large number of quantum gates. Therefore, these methods are difficult to be realized in current quantum computer.

### DOCUMENTS INCORPORATED BY REFERENCE IN THEIR ENTIRETIES

Non-patent document 1. Pierre-Luc Dallaire-Demers and Frank K. Wilhelm, “Method to efficiently simulate the thermodynamic properties of the Fermi-Hubbard model on a quantum computer”, PHYSICAL REVIEW A 93, 032303 (2016);
Non-patent document 2. Taichi Kosugi and Yu-ichiro Matsushita, “Construction of Green's functions on a quantum computer: applications to molecular systems”, arXiv:1908. 03902, Aug. 13, 2019;
Non-patent document 3. A. Peruzzo et al., “A variational eigenvalue solver on a photonic quantum processor”, Nature Communications, 5:4213 (2014);
Non-patent document 4. A. Szabo and N. S. Ostlund, “Modern Quantum Chemistry”, Dover Publications (1996);
Non-patent document 5. A. G. Taube and R. J. Bartlett, “New perspectives on unitary coupled-cluster theory”, International Journal of Quantum Chemistry, Vol 106, 3393-3401 (2006);
Non-patent document 6. G. Ortiz, J. E. Gubernatis, E. Knill, and R. Laflamme, “Quantum algorithms for fermionic simulations”, Phys. Rev. A 64, 022319 (2001);
Non-patent document 7. S. Bravyi and A. Kitaev, “Fermionic quantum computation”, Annals of Physics, Vol. 298, 210-226 (2002);
Non-patent document 8. J. C. Spall, “Multivariate stochastic approximation using a simultaneous perturbation gradient approximation”, IEEE Transactions on Automatic Control 37, 332-341 (1992).

### SUMMARY

Example embodiments of the inventive concepts are devised to solve the above problems, and provide an analysis method and an analysis system capable of calculating a Green's function while reducing the number of quantum gates required for calculation by a quantum processor.

According to an example embodiment, an analysis method includes converting, by a classical processor, a Hamiltonian operator of a sub-system corresponding to a basis function and an operator corresponding to an overlapping matrix of the basis function into a spin operator, basis function representing an N±1 electromagnetic field with respect to an analysis target substance having N electrons, where the N is a natural number; calculating, by a quantum processor, an expected value of the spin operator, calculating, by the classical processor, an element of a Hamiltonian matrix corresponding to the Hamilton operator and an element of the overlapping matrix based on the expected value; and calculating a one-electron Green's function, based on the Hamiltonian matrix and the overlapping matrix.

According to an example embodiment, an analysis system includes a classical processor configured to convert a covert a Hamiltonian operator of a sub-system corresponding to a basis function and an operator corresponding to an overlapping matrix of the basis function into a spin operator, the basis function representing an N±1 electromagnetic field with respect to an analysis target substance having N electrons, where N represents a natural number, calculate an element of a Hamiltonian matrix corresponding to the Hamiltonian operator and an element of the overlapping matrix, based on an expected value of a spin operator, and calculate a one-electron Green's function, based on the Hamiltonian matrix and the overlapping matrix; and a quantum processor configured to calculate the expected value of the spin operator.

### BRIEF DESCRIPTION OF THE FIGURES

The above and other objects and features of the inventive concepts will become apparent by describing in detail example embodiments thereof with reference to the accompanying drawings.

FIG. 1 is a block diagram illustrating a configuration of an analysis system according to an example embodiment of the inventive concepts.

FIG. 2 is a flowchart illustrating performing a calculation on a basis state of a substance having ‘N’ electron numbers.

FIG. 3 is a flowchart illustrating calculating a Green's function.

FIG. 4 is a flowchart illustrating operation S305 performed by a classical processor.

FIG. 5A is a graph illustrating a calculation result of an electronic state of a hydrogen molecule.

FIG. 5B is a graph illustrating a calculation result of an electronic state of a hydrogen molecule.

FIG. 5C is a graph illustrating a calculation result of an electronic state of a hydrogen molecule.

FIG. 5D is a graph illustrating a calculation result of an electronic state of a hydrogen molecule.

FIG. 6 is a table illustrating a difference between the lowest occupied energy and the highest occupied energy calculated from an energy state density.

### DETAILED DESCRIPTION

Hereinafter, example embodiments to which the inventive concepts are applied will be described in detail with reference to the drawings.

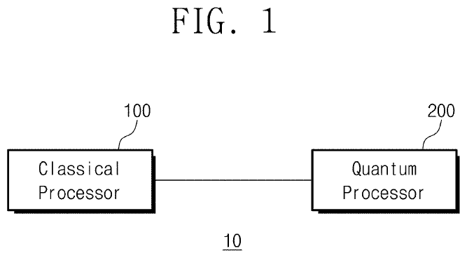

FIG. 1 is a block diagram illustrating a configuration of an analysis system 10 according to an example embodiment of the inventive concepts. Referring to FIG. 1, the analysis system 10 may include a classical processor 100 and a quantum processor 200. The analysis system 10 is a system that analyzes an electronic state of an analysis target substance. The number of electrons of the analysis target substance may be represented by ‘N’ (where ‘N’ is a natural number).

The classical processor 100 may be included in a classical computer like a personal computer, a Neumann-type computer of a server, or the like. The classical processor 100 may be configured to execute a command (computer program) stored in memory. The processor may include processing circuitry such hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), and programmable logic unit, a microprocessor, application-specific integrated circuit (ASIC), etc. The memory may include, for example, various types of non-transitory computer-readable media, and may be configured to store the commands. The non-transitory computer-readable media may include various types of recording media (e.g., tangible storage mediums). The non-transitory computer-readable media may include, for example, magnetic recording media (e.g., a flexible disk, a magnetic tape, a hard disk drive), magneto-optical recording media (e.g., an optical magnetic disk), a CD-ROM (Read Only Memory), a CD-R, a CD-R/W, and/or a semiconductor memory (e.g., a mask ROM, a Programmable ROM (PROM), an Erasable ROM (PROM), a Flash ROM, and/or a random access (RAM)). The computer program may be provided to the computer by various types of transitory computer readable media. The transitory computer readable medium, for example, may be configured to store the commands as electrical signals, optical signals, and/or electromagnetic waves. The transitory computer readable medium may be configured to supply the computer program to the computer through a wired communication path such as a wire, an optical fiber, and/or a wireless communication path.

The quantum processor 200 may be included in be a quantum computer. For example, the quantum processor 200 may include a quantum gate and be configured to perform quantum calculations using the quantum gate. The classical processor 100 and the quantum processor 200 may be connected to enable communication. For example, the classical processor 100 and the quantum processor 200 may be connected via a wired and/or wireless communication path and/or network, and may be configured to perform bi-directional data transmission.

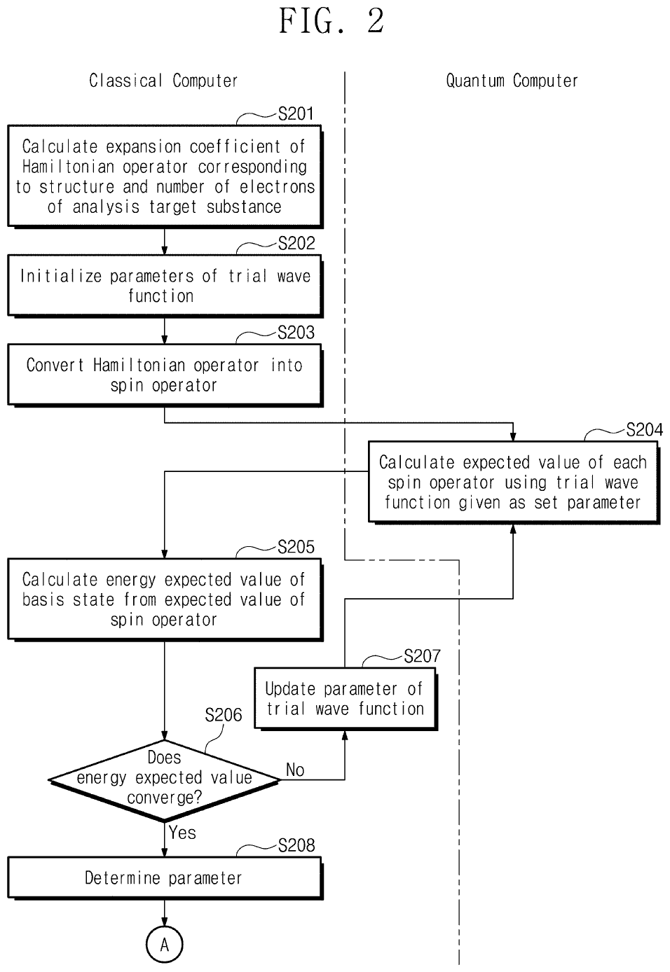

FIGS. 2 to 4 are flowcharts illustrating a flow of processing by the analysis system 10. Hereinafter, processing of the analysis system 10 will be described with reference to FIGS. 2 to 4.

An analysis method according to an example embodiment of the inventive concepts may include a first process (FIG. 2) that calculates the energy and the wave function of a basis state of a substance and a second process that calculates a Green function (e.g., a one-electron Green's function) using a result obtained by the first process. In addition, when the energy of the basis state and the wave function of the basis state are already known, the first process may be omitted.

First, the first process will be described. FIG. 2 is a flowchart illustrating a flow of processing that calculates a basis state of a substance having ‘N’ electron numbers. The substance may include, for example, reversible quantum logic gates. As illustrated in FIG. 2, the classical processor 100 and the quantum processor 200 may be configured to calculate the basis state depending on a VQE (Variational Quantum Eigensolver) method. For example, the basis state may be calculated based on the VQE method described in Non-patent document 3, which is incorporated by reference herein in its entirety.

For example, in operation S201, the classical processor 100 calculates an expansion coefficient that constitutes a Hamiltonian operator ‘H’ corresponding to structural information and ‘N’ number of electrons of an analysis target substance.

In this case, the Hamiltonian operator ‘H’ is expressed in Equation 1 below, hᵢⱼ and Vᵢⱼₖₗ on the right side of Equation 1 are expansion coefficients.

$$[ Equation 1 ]$$

$$H = {\sum }_{ij} {h}_{ij} {c}_{i}^{†} {c}_{j} + \frac{1}{2} {\sum }_{ijkl} {V}_{ijkl} {c}_{i}^{†} {c}_{j}^{†} {c}_{k} {c}_{l} \qquad ( 1 )$$

In addition, cᵢ, cⱼ, cₖ, cₗ are annihilation operators of electrons, and cᵢ†, cj† are creation operators of electrons. The subscripts i, j, k, and l indicate an index number of the base function. For example, the one-electron wave function (e.g., canonical orbital) of a Hartree-Fock method may be used as a basis function. Non-patent document 4, which is incorporated by reference herein in its entirety, discloses an example Hartree-Fock method, but other functions and/or methods may be used.

The expansion coefficients hᵢⱼ and Vᵢⱼₖₗ are given in the following form in an atomic unit system, and are calculated by the classical processor 100 in operation S201.

$$\begin{matrix} [ Equation 2 ] \\ {h}_{ij} = \int {φ}_{i}^{*} ( r , σ ) [ - \frac{1}{2} {∇}^{2} + v ( r ) ] {φ}_{j} ( r , σ ) {d}^{3} rd σ \\ [ Equation 3 ] & ( 2 ) \\ {V}_{ijkl} = \int {φ}_{i}^{*} ( {r}_{1} , {σ}_{1} ) {φ}_{j}^{*} ( {r}_{2} , {σ}_{2} ) \frac{1}{\vert {r}_{1} - {r}_{2} \vert} {φ}_{k} ( {r}_{2} , {σ}_{2} ) {φ}_{l} ( {r}_{1} , {σ}_{1} ) {d}^{3} {r}_{1} {d}^{3} {r}_{2} d {σ}_{1} d {σ}_{2} & ( 3 )\end{matrix}$$

In equations 2 and 3, φ(r,σ) represents the basis function, r represents a spatial coordinate, and σ represents a spin coordinate. * of the subscript indicates a complex conjugate. v (r) represents a general potential and contains a Coulomb potential that is created by an atomic nuclei in the substance. Vᵢⱼₖₗ represents the Coulomb potential that occurs between electrons.

Subsequently, in operation S202, the classical processor 100 initialize parameters of a trial wave function with regard to a wave function |N, 0> in the basis state of an ‘N’ electromagnetic field. For example, the classical processor 100 may set initial values of the parameters of the trial wave function |N, 0>. In this case, the wave function |N, n> represents the wave function of n-th energy level of the ‘N’ electromagnetic field, where ‘n’ is an integer greater than or equal to 0. Therefore, in the case of n=0, |N, n> represents the wave function in the basis state, and in the case of n>1, |N, n> represents the wave function in an excited state.

In this case, the wave function |N, 0> of the basis state of the ‘N’ electromagnetic field may be expressed in a form including a parameter set {θ}, as illustrated in Equation 4.

[Equation 4]

|N,0 [symbol] =U(θ)|HF [symbol] (4)

In equation 4, |HF> represents the wave function of the basis state of the electrons represented by the Hartree-Fock method. U(θ) represents a unitary operator including the parameter θ, and may be, for example, a function using a unitary coupled cluster method. For example, Non-patent document 5, which is incorporated by reference herein in its entirety, discloses an example unitary coupled cluster method, but other functions and/or methods may be used.

The analysis system 10 according to an example embodiment of the inventive concepts calculates an energy expected value <N, 0 |H| N, 0>, which is the expected value of the Hamiltonian operator, using the trial wave function |N, 0>. In operation S203, the classical processor 100 converts the Hamiltonian operator into a spin operator. The classical processor 100 converts the Hamiltonian operator ‘H’ into a set of spin operators, using, for example, a Jordan-Wigner transform (as described in Non-patent document 6, which is incorporated by reference herein in its entirety), a Bravi-Kitaev transform (as described in Non-patent document 7, which is incorporated by reference herein in its entirety), and/or the like. For example, the classical processor 100 may be configured to perform a conversion as in Equation 5.

$$[ Equation 5 ]$$

$$H = {\sum }_{α} {h}_{α} {P}_{α} \qquad ( 5 )$$

In this case, α represents a subscript indicating an expansion term when expanded by the spin operator. h_{α} represents the expansion coefficient. As illustrated in Equation 6 below, with the number of basis functions including a spin freedom degree as ‘M’, P_{α}, may be expressed as a product of M spin operators p_{iα}. In addition, each spin operator p_{iα} may have a value of a spin operator X, Y, Z or an identity operator I.

$$[ Equation 6 ]$$

$${P}_{α} = {⊗}_{i = 1}^{M} {p}_{i α} \qquad ( 6 )$$

In operation S204, the quantum processor 200 calculates the expected value of each spin operator using the trial wave function given as a set parameter. For example, the quantum processor 200 may calculate the expected value <N, 0 |Pα| N, 0> of each spin operator P_{α}.

In operation S205, the classical processor 100 calculates the energy expected value E₀^{N} of the basis state of the ‘N’ electromagnetic field from the expected value <N, 0 |Pα| N, 0> of P_{α} obtained in operation S204. For example, the classical processor 100 may calculate the energy expected value E₀^{N} of the basis state using Equation 7 below.

$$[ Equation 7 ]$$

$${E}_{0}^{N} = {\sum }_{α} {h}_{α} 〈 N , 0 \vert {P}_{α} \vert N , 0 〉 \qquad ( 7 )$$

By iterative calculation, the value of the parameter θ is determined such that the energy expected value thus obtained is a minimum value. For example, the process of operation S204 described above and operations S205 to S207 described later are repeated. In addition, this iterative process uses an existing minimization routine, for example, a Simultaneous perturbation stochastic approximation method. For example, Non-patent document 8, which is incorporated by reference herein in its entirety, describes an example Simultaneous perturbation stochastic approximation method, but other methods may be used.

In operation S206, the classical processor 100 determines whether the energy expected value calculated in operation S205 converges. For example, when a difference between the energy expected value calculated in the t-th operation S205 and the energy expected value calculated in the t+1-th operation S205 is equal to or less than a specified difference, the classical processor 100 may determine that the energy expected value converges.

When the energy expected value does not converge (No in operation S206), the flow proceeds to operation S207. In operation S207, the classical processor 100 updates the value of the parameter θ of the trial wave function. The classical processor 100 may be configured to perform the update, for example, by changing the value of the parameter θ depending on a specified change rule. After operation S207, the flow returns to operation S204. For example, the expected value of the spin operator is calculated using the trial wave function given as a parameter updated by the quantum processor 200.

When the energy expected value converges (Yes in operation S206), in operation S208, the classical processor 100 determines the parameter of the wave function in the basis state of the ‘N’ electromagnetic field. For example, the classical processor 100 may be configured to confirm the current parameter value as the parameter value of the wave function in the basis state of the ‘N’ electromagnetic field. Thereby, the wave function given as the confirmed parameter becomes the wave function in the basis state of the ‘N’ electromagnetic field of the analysis target substance. In addition, the converged energy expected value is the energy expected value in the basis state of the ‘N’ electromagnetic field of the analysis target substance. Therefore, by the process illustrated in FIG. 2 by the analysis system 10, the wave function and the energy expected value in the basis state of the ‘N’ electromagnetic field are calculated.

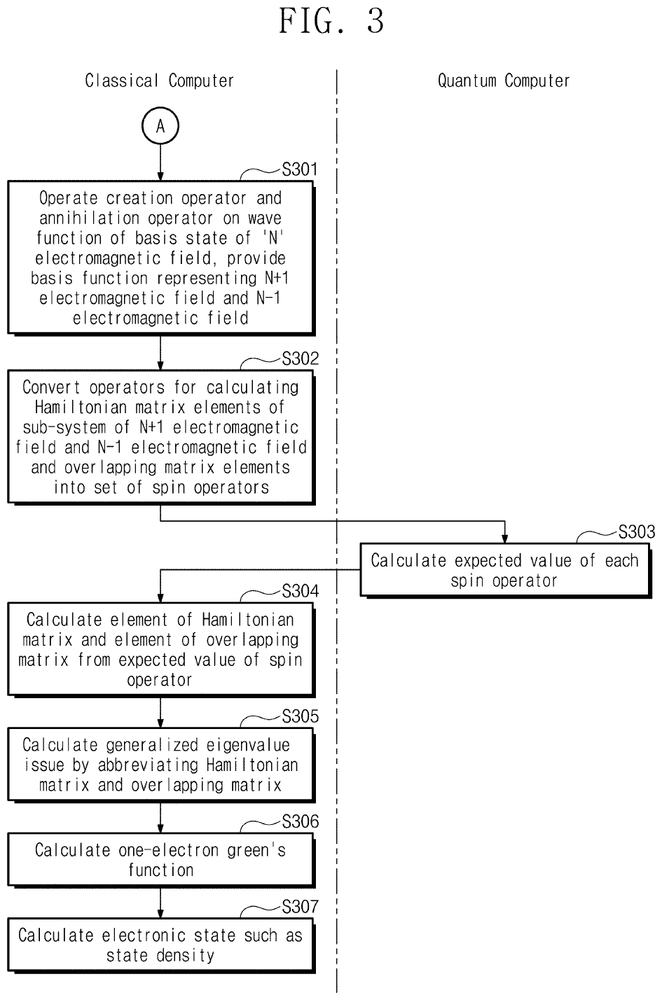

Subsequently, a second process that calculates the Green's function using the result obtained in the first process (FIG. 2) will be described. FIG. 3 is a flowchart illustrating a flow of processing that calculates the Green's function. Hereinafter, FIG. 3 will be described.

In operation S301, using the wave function |N, 0> of the basis state calculated by the first process, the classical processor 100 defines a basis function B_{I}^{N+1}> that expresses a sub-system of an N+1 electromagnetic field of the analysis target substance and a basis function B_{I}^{N-1}> that expresses a sub-system of an N−1 electromagnetic field of the analysis target substance as in Equation 8 and Equation 9 below, respectively. For example, the classical processor 100 may be configured to provide the basis function representing the sub-system of the N+1 electromagnetic field and the basis function representing the sub-system of the N−1 electromagnetic field by applying the creation operator of electrons and the annihilation operator of electrons to the wave function of the basis state of the ‘N’ electromagnetic field.

[Equation 8]

|B_{I}^{N+1} [symbol] =C_{I}^{†}|N,0 [symbol] (8)

[Equation 9]

|B_{I}^{N-1} [symbol] =C_{I}|N,0 [symbol] (9)

In this case, C_{I} represents a generalized annihilation operator, and C_{I}† represents a generalized creation operator. The generalized annihilation operator is an operator that decays one electron by a combination of one or more creation annihilation operators, and the generalized creation operator is an operator that generates one electron by a combination of one or more creation annihilation operators. Specifically, C_{I} and C_{I}† may include operators such as (A) and (B) below. In addition, C_{I} and C_{I}† may include only the operator of (A), may include only the operator of (B), or may include the operator of (A) and the operator of (B).

The operator of (A) may indicate an operator from one creation annihilation operator (e.g., one creation annihilation operator used when the Hamiltonian operator is expanded in Equation 1).

In this case, C_{I}, C_{I}† is expressed as represented by equation 10.

[Equation 10]

C_{I=i}=cᵢ, C_{I=i}^{†}=cᵢ^{†} (10)

The operator of (B) may indicate an operator that is represented by a plurality of creation operators and a plurality of annihilation operators (e.g., operator that is represented by a combination (product of the creation operator and the annihilation operator) of the creation operator and the annihilation operator used when the Hamiltonian operator is expanded in Equation 1).

In this case, C_{I} is an operator in which q (q represents an integer greater than or equal to 1) creation operators and q+1 annihilation operators are combined. C_{I}† is an operator in which q annihilation operators and q+1 creation operators are combined. For example, when a combination of three creation operators and annihilation operators in total is represented, it is expressed as represented by equation 11.

[Equation 11]

C_{I=ijk}=cᵢcⱼ^{†}cₖ, C_{I=ijk}^{†}=cₖ^{†}cⱼcᵢ^{†} (11)

In this case, C_{I} represents a combination of two annihilation operators and one creation operator, and C_{I}† represents a combination of two creation operators and one annihilation operator.

In addition, the number of creation and annihilation operators to be combined is not limited to three, and any odd number of creation and annihilation operators such as five, seven, etc. is also possible. A user may specify which combination to use and/or the computer 100 may also adjust the number of creation and annihilation operators to be combined.

When the operators of (A) and (B) described above are collectively mentioned, C_{I} represents an operator in which q (q is an integer of 0 or more) creation operators and q+1 annihilation operators are combined, and C_{I}† represents an operator in which q (q is an integer of 0 or more) annihilation operators and q+1 creation operators are combined.

The analysis system 10 calculates a Hamiltonian H^{N+1} and H^{N-1} that is represented by a matrix of the sub-system of the N+1 electromagnetic field and the N−1 electromagnetic field expressed using the basis functions |B_{I}^{N+1}> and |B_{I}^{N-1}> defined as described above and matrices (e.g., overlapping matrices S^{N+1} and S^{N-1}) representing overlapping of the basis functions of the Hamiltonian as follows.

In operation S302, the classical processor 100 converts operators for calculating elements of the Hamiltonian matrix (matrix corresponding to the Hamiltonian operator) of the sub-system of the N+1 electromagnetic field and the N−1 electromagnetic field and elements of the overlapping matrix corresponding to the Hamiltonian matrix into a set of the spin operators.

Using the above basis functional systems |B_{I}^{N+1}> and |B_{I}^{N-1}>, Hᵢⱼ^{N+1} and Hᵢⱼ^{N-1} which are components (e.g., I and J matrix elements) of I rows and J columns of the Hamiltonian matrices H^{N+1} and H^{N-1} of the sub-system of the N+1 electromagnetic field and the N−1 electromagnetic field are given as in Equation 12 and Equation 13 below. S_{IJ}^{N+1} and S_{IJ}^{N-1}, which are the components (e.g., I and J matrix elements) of I rows and J columns of the overlapping matrices S^{N+1} and S^{N-1} corresponding to the Hamiltonian matrix are given as described in Equations 14 and 15 below.

[Equation 12]

H_{IJ}^{N+1}= [symbol] B_{I}^{N+1}|H|B_{J}^{N+1} [symbol] = [symbol] N,0|C_{I}HC_{J}^{†}|N,0 [symbol] (12)

[Equation 13]

H_{IJ}^{N-1}= [symbol] B_{I}^{N-1}|H|B_{J}^{N-1} [symbol] = [symbol] N,0|C_{I}^{†}HC_{J}|N,0 [symbol] (13)

[Equation 14]

S_{IJ}^{N+1}= [symbol] B_{I}^{N+1}|B_{J}^{N+1} [symbol] = [symbol] N,0|C_{I}C_{J}^{†}|N,0 [symbol] (14)

[Equation 15]

H_{IJ}^{N-1}= [symbol] B_{I}^{N-1}|B_{J}^{N-1} [symbol] = [symbol] N,0|C_{I}^{†}C_{J}|N,0 [symbol] (15)

In operation S302, the classical processor 100 may be configured to convert each of the operators C_{I}HC_{J}^{†}, C_{I}^{†}HC_{J}, C_{I}C_{J}^{†}, and C_{I}^{†}C_{J} indicated in <N, 0| and |N, 0> in the above four Equations into a set of spin operators, using the Jordan-Wigner transform, the Bravi-Kitaev transform, and/or the like. For example, in operation S302, the classical processor 100 may be configured to convert the Hamiltonian operators C_{I}HC_{J}^{†} and C_{I}^{†}HC_{J} of the sub-system corresponding to the basis function that represents the N±1 electromagnetic field with regard to the analysis target substance having ‘N’ electrons and the operators C_{I}C_{J}^{†} and C_{I}^{†}C_{J} corresponding to the overlapping matrix of the basis function into the spin operator. In this case, the classical processor 100 may convert and express the operator C_{I}HC_{J}^{†} as a product of the annihilation operator, the Hamiltonian operator, and the creation operator, the operator C_{I}^{†}HC_{J} as a product of the creation operator, the Hamiltonian operator, and the annihilation operator, the operator C_{I}C_{J}^{†} as a product of the annihilation operator and the creation operator, the operator C_{I}^{†}C_{J} as a product of the creation operator and the annihilation operator into the spin operator, respectively. For example, in this case, the classical processor 100 performs the conversion as described in Equation 16, Equation 17, Equation 18, and Equation 19 below.

$$[ Equation 16 ]$$

$$\begin{matrix}{C}_{I} {HC}_{J}^{†} = {\sum }_{α} {h}_{IJ , α}^{N + 1} {P}_{α} \\ [ Equation 17 ] & ( 16 ) \\ {C}_{I}^{†} {HC}_{J} = {\sum }_{α} {h}_{IJ , α}^{N - 1} {P}_{α} \\ [ Equation 18 ] & ( 17 ) \\ {C}_{I} {C}_{J}^{†} = {\sum }_{α} {s}_{IJ , α}^{N + 1} {P}_{α} \\ [ Equation 19 ] & ( 18 ) \\ {C}_{I}^{†} {C}_{J} = {\sum }_{α} {s}_{IJ , α}^{N - 1} {P}_{α} & ( 19 )\end{matrix}$$

In Equation 16, Equation 17, Equation 18, and Equation 19 case, α represents a subscript indicating the expansion term when expanded to the spin operator and h_{IJ,α}^{N+1}, h_{IJ,α}^{N-1}, s_{IJ,α}^{N+1}, and s_{IJ,α}^{N-1} represent expansion coefficients. With the number of basis functions including the spin freedom degree as ‘M’, Pα is represented by a direct product of ‘M’ spin operators p_{iα} as illustrated in Equation 20 below. In addition, each spin operator p_{iα} may have the value of the spin operators X, Y, Z or the identity operator I.

$$[ Equation 20 ]$$

$${P}_{α} = {⊗}_{i = 1}^{M} {p}_{i α} \qquad ( 20 )$$

In operation S303, the quantum processor 200 calculates the expected value of each spin operator using the wave function |N, 0> of the basis state calculated by the first process. For example, the quantum processor 200 may be configured to calculate the expected value <N, 0 |Pα| N, 0> of each spin operator P_{α}.

In operation S304, the classical processor 100 calculates each matrix element H_{IJ}^{N+1}, H_{IJ}^{N-1}, S_{IJ}^{N+1}, and S_{IJ}^{N-1} from the expected value <N, 0 |Pα| N, 0> of P_{α} obtained in operation S303. For example, the classical processor 100 may be configured to calculate the following Equation 21, Equation 22, Equation 23, and Equation 24.

$$[ Equation 21 ]$$

$$\begin{matrix}{H}_{IJ}^{N + 1} = {\sum }_{α} {h}_{IJ , α}^{N + 1} 〈 N , 0 \vert {P}_{α} \vert N , 0 〉 \\ [ Equation 22 ] & ( 21 ) \\ {H}_{IJ}^{N - 1} = {\sum }_{α} {h}_{IJ , α}^{N - 1} 〈 N , 0 \vert {P}_{α} \vert N , 0 〉 \\ [ Equation 23 ] & ( 22 ) \\ {S}_{IJ}^{N + 1} = {\sum }_{α} {s}_{IJ , α}^{N + 1} 〈 N , 0 \vert {P}_{α} \vert N , 0 〉 \\ [ Equation 24 ] & ( 23 ) \\ {S}_{IJ}^{N - 1} = {\sum }_{α} {s}_{IJ , α}^{N - 1} 〈 N , 0 \vert {P}_{α} \vert N , 0 〉 & ( 24 )\end{matrix}$$

Subsequently, the classical processor 100 calculates the one-electron Green's function, based on the Hamiltonian matrix and the overlapping matrix from which the elements are calculated. For example, the classical processor 100 may be configured to perform processing described below.

In operation S305, the classical processor 100 eliminates a nonregularity of the overlapping matrices S^{N+1} and S^{N-1} resulting from a linear dependence of the basis functions |B_{I}^{N+1}> and |B_{I}^{N-1}>. For example, the classical processor 100 may be configured to abbreviate the Hamiltonian matrix and the overlapping matrix. Then, the classical processor 100 may calculate a generalized eigenvalue issue with regard to the abbreviated Hamiltonian and overlapping matrices.

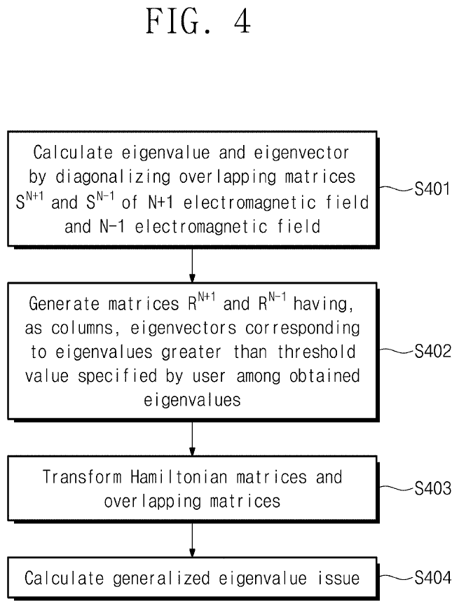

FIG. 4 is a flowchart illustrating a flow of operation S305 that is performed by the classical processor 100. Hereinafter, operation S305 will be described in detail with reference to FIG. 4.

In operation S401, the classical processor 100 diagonalizes the overlapping matrices S^{N+1} and S^{N-1} to calculate each eigenvalue and eigenvector.

Subsequently, in operation S402, the classical processor 100 selects eigenvalues greater than 0 among the eigenvalues obtained in each matrix, and generates the matrices R^{N+1} and R^{N-1} having eigenvectors corresponding to the selected eigenvalues as columns. For example, the matrix R^{N+1} may be a matrix in which each column is constructed by an eigenvector corresponding to an eigenvalue greater than 0 of the overlapping matrix S^{N+1} As in the above description, the matrix R^{N-1} may be a matrix in which each column is constructed by an eigenvector corresponding to an eigenvalue greater than 0 of the overlapping matrix S^{N-1}. In addition, the classical processor 100 may be configured to select an eigenvalue greater than 0, for example, by selecting an eigenvalue above a threshold value specified by the user in advance.

Subsequently, in operation S403, the classical processor 100 transforms the Hamiltonian matrices H^{N+1} and H^{N-1}, and overlapping matrices S^{N+1} and S^{N-1} using the matrices R^{N+1} and R^{N-1} as in Equation 25, Equation 26, Equation 27, and Equation 28. In Equation 25 through Equation 28, ‘†’ represents a complex transpose matrix (Hermitian matrix).

[Equation 25]

\tilde{H}^{N+1}=(R^{N+1})^{†}H^{N+1}R^{N+1} (25)

[Equation 26]

\tilde{H}^{N-1}=(R^{N-1})^{†}H^{N-1}R^{N-1} (26)

[Equation 27]

\tilde{S}^{N+1}=(R^{N+1})^{†}S^{N+1}R^{N+1} (27)

[Equation 28]

\tilde{S}^{N-1}=(R^{N-1})^{†}S^{N-1}R^{N-1} (28)

In the above Equation 25, the matrix H^{˜N}^{₊}¹ on the left side represents a matrix after the transform of matrix H^{N+1}. In Equation 26 above, the matrices H^{˜N}^{_{−}}¹ on the left side represent a matrix after the transform of the matrix H^{N-1}. In Equation 27 above, the matrix S^{˜N+1} on the left side represents a matrix after the transform of the matrix S^{N+1} In Equation 28 above, the matrix S^{˜N-1} on the left side represents a matrix after the transform of the matrix S^{N-1}.

Subsequently, in operation S404, the classical processor 100 solves the generalized eigenvalue issue that is expressed by the following Equation 29 and Equation 30, using the modified matrices H^{˜N}^{₊}¹, H^{˜N-1}, S^{˜N}^{₊}¹, and S^{˜N-1} obtained by the above-described operations. In this way, the classical processor 100 calculates the energy eigenvalue Eᵥ^{N+1} of the N+1 electromagnetic field, the eigenvector Z_{Jv}^{N+1} Corresponding to this eigenvalue, the energy eigenvalue Eᵥ^{N-1} of the N−1 electromagnetic field, and the eigenvector Z_{Jv}^{N-1} corresponding to the eigenvalue. In this example embodiment, v is a subscript indicating the energy level. In addition, matrix elements are represented by subscripting each matrix. For example, H^{˜}_{IJ}^{N}^{₊}¹ represent the (i, j) component of the matrix H^{N}^{₊}¹. The same is true for other matrices.

$$[ Equation 29 ]$$

$$\begin{matrix}{\sum }_{J} {\tilde{H}}_{IJ}^{N + 1} {Z}_{Jv}^{N + 1} = {E}_{v}^{N + 1} {\sum }_{J} {\tilde{S}}_{IJ}^{N + 1} {Z}_{Jv}^{N + 1} \\ [ Equation 30 ] & ( 29 ) \\ {\sum }_{J} {\tilde{H}}_{IJ}^{N - 1} {Z}_{Jv}^{N - 1} = {E}_{v}^{N - 1} {\sum }_{J} {\tilde{S}}_{IJ}^{N - 1} {Z}_{Jv}^{N - 1} & ( 30 )\end{matrix}$$

Again, referring to FIG. 3, the subsequent processing will be described.

After operation S305, in operation S306, the classical processor 100 calculates the Green's function (one-electron Green's function). For example, the classical processor 100 may be configured to calculate Gᵢⱼ(ω), which is the (i, j) component of the Green's function at frequency or energy ω, using the energy expected value E₀^{N}, the energy eigenvalues Eᵥ^{N+1} and Eᵥ^{N-1}, the wave functions |N, 0>, the annihilation operator cᵢ of electrons, the basis functions |B_{I}^{N+1}>, B_{I}^{N-1}>, the matrices R^{N+1} and R^{N-1}, and values of eigenvectors Z_{Jv}^{N+1}, Z_{Jv}^{N-1} as follows (refer to Equations 31 to 35). In addition, i and j are the same as the above-mentioned subscripts of the basis function that expands the Hamiltonian operator. * indicates complex conjugate. η represents a positive infinite number, and may be approximated by a finite positive number computationally. i denoted with η represents an imaginary unit. Z^{N+1} represents a matrix having Z_{Jv}^{N+1} as a component, and Z^{N-1} represents a matrix having Z_{Jv}^{N-1} as a component. In Equations 34 and 35, (R^{N±1} Z^{N±1})_{Iv} represents the I and v components of the matrix R^{N±1} Z^{N±1} which is the product of the matrix R^{N±1} and the matrix Z^{N±1}.

$$[ Equation 31 ]$$

$$\begin{matrix}{G}_{ij} ( ω ) = {\sum }_{v} \frac{{f}_{iv}^{N + 1} {f}_{jv}^{N + 1 *}}{ω - ( {E}_{v}^{N + 1} - {E}_{0}^{N} ) + i η} + {\sum }_{v} \frac{{f}_{iv}^{N - 1} {f}_{jv}^{N - 1 *}}{ω + ( {E}_{v}^{N - 1} - {E}_{0}^{N} ) + i η} \\ [ Equation 32 ] & ( 31 ) \\ {f}_{iv}^{N + 1} = 〈 N , 0 \vert {c}_{i} \vert N + 1 , v 〉 \\ [ Equation 33 ] & ( 32 ) \\ {f}_{iv}^{N - 1} = 〈 N - 1 , v \vert {c}_{i} \vert N , 0 〉 \\ [ Equation 34 ] & ( 33 ) \\ \vert N + 1 , v 〉 = {\sum }_{I} {( {R}^{N + 1} {Z}^{N + 1} )}_{Iv} \vert {B}_{I}^{N + 1} 〉 \\ [ Equation 35 ] & ( 34 ) \\ \vert N - 1 , v 〉 = {\sum }_{I} {( {R}^{N - 1} {Z}^{N - 1} )}_{Iv} \vert {B}_{I}^{N - 1} 〉 & ( 35 )\end{matrix}$$

By doing this, the Green's function for analyzing the electronic state of substance may be obtained. As described above, the analysis method according to the embodiment of the inventive concepts calculates a frequency-based Green's function, not a time-based Green's function, using the classical processor 100 and the quantum processor 200. Since the analysis method according to the example embodiment of the inventive concepts uses the quantum processor 200 only for calculating the expected value of the spin operator, it is possible to reduce and/or minimize the number of required quantum gates compared to the conventionally proposed calculation method, reducing the hardware requirements of the quantum computer. For example, the analysis method according to an example embodiment of the inventive concepts may calculate the Green's function while reducing and/or minimizing the number of quantum gates required for calculation by the quantum processor, and, thus, reducing the number of qubits the quantum computer needs to maintain in a coherent superposition, allowing for the easier production of the quantum computer. Furthermore, the reduced and/or minimized number of quantum gates may allow for more efficient allocation of quantum computing resources, including reduced energy consumption and/or redundant processing, thereby improving the functionality of the quantum computer.

Using the Green's function G thus obtained, it is possible to calculate physical quantities related to the various electronic states of the target substance. Therefore, the classical processor 100 may calculate the electronic state using the calculation result of operation S306.

For example, in operation S307, the classical processor 100 may calculate the electronic state of the substance using the one-electron Green's function calculated in operation S306. Thereby, the electronic state may be calculated while reducing and/or minimizing the number of quantum gates required for calculation by a quantum processor.

Hereinafter, an example of calculation of the electronic state using a Green's function will be described. For example, the energy state density D(O) may be obtained by calculation, based on the following Equation 36.

$$[ Equation 36 ]$$

$$\begin{matrix}D ( ω ) = & - \frac{1}{π} Im {\sum }_{i} {G}_{ii} ( ω ) \\ = & {\sum }_{i} {\sum }_{v} {\vert {f}_{iv}^{N + 1} \vert}^{2} δ ( ω - {E}_{v}^{N + 1} + {E}_{0}^{N} ) + \\ & {\sum }_{i} {\sum }_{v} {\vert {f}_{iv}^{N - 1} \vert}^{2} δ ( ω + {E}_{v}^{N - 1} - {E}_{0}^{N} )\end{matrix} \qquad ( 36 )$$

In addition, in the above Equation 36, π represents a circumference, Im represents the imaginary part, δ represents the delta function, ∥ represents an absolute value. Practically, the delta function may be approximated as a function having a finite width.

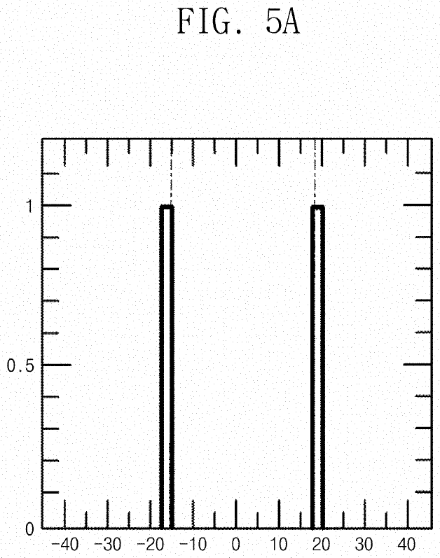

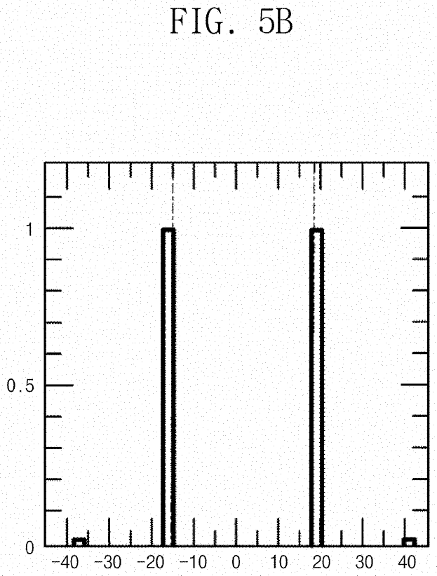

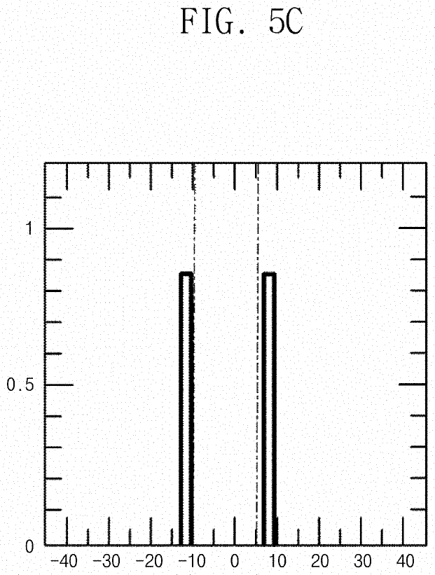

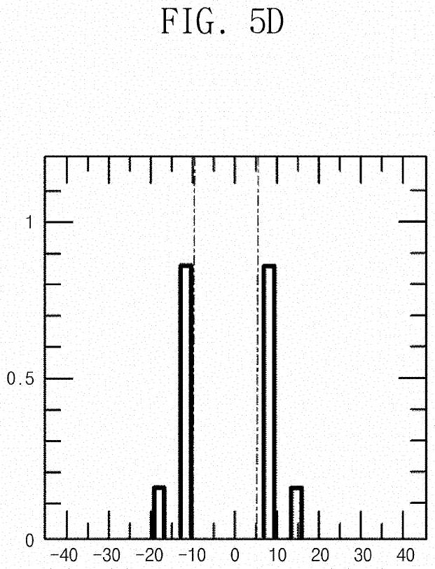

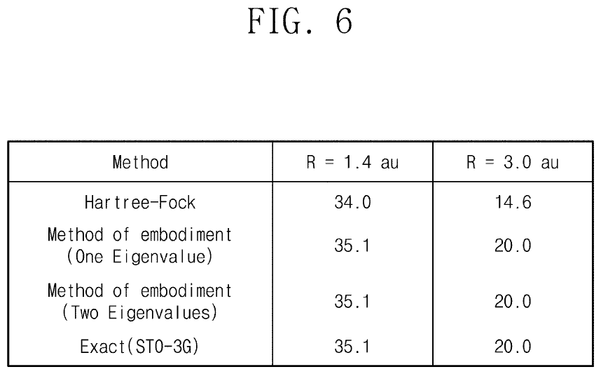

FIGS. 5A, 5B, 5C, 5D, and 6 illustrate results of calculating a Green's function described above and calculating an electronic state of a hydrogen molecule, by pseudo-quantum calculation using a classical processor. In this case, the results of the case where a distance between hydrogen atoms is 1.4 au (refer to FIGS. 5A and 5B) and 3.0 au (refer to FIGS. 5C and 5D) are indicated wherein 1 au represents the average distance between the proton and electron in a Bohr model hydrogen atom, and is equal to 5.29×10⁻¹¹ m. In this calculation, a unitary coupled cluster method is used to calculate the basis state of the first process. A canonical orbit of the Hartree-Fock method is used as the basis function that expands the Hamiltonian operator. A function system called STO-3G may be used as a function that expands the canonical orbit of the Hartree-Fock method.

In FIGS. 5A to 5D, vertical axes represents coefficients of the delta function of Equation 36, |fᵢᵥ^{N}^{₊}¹|², |fᵢᵥ^{N}^{_{−}}¹|², and horizontal axes represents energy (in units of eV). The results represented in FIGS. 5A to 5D are the results when one creation operator and one annihilation operator (cᵢ or cᵢ†) are used as the generalized creation and annihilation operators described above. FIGS. 5A and 5C represent results when one eigenvalue is selected in operation S402 described above, and FIGS. 5B and 5D represent results when two eigenvalues are selected in operation S402 described above.

FIG. 6 illustrates a difference between the lowest occupied energy and the highest occupied energy calculated from an energy state density in units of eV. For comparison, results according to the Hartree-Fock method are written together. Referring to FIG. 6, it may be recognized that a calculation precision of the electronic state according to the example embodiment is relatively high.

The example embodiments have been described above. In addition, the inventive concepts are not limited to the above-described embodiments, and may be changed without departing from spirit and scope of the inventive concept.

For example, in the above-described embodiment, the basis state is calculated by the classical processor 100 and the quantum processor 200 depending on the VQE (Variational Quantum Eigensolver) method, but calculation by other methods is also possible. That is, the above-described first process is only an example, and the basis state may be calculated by another process. When the basis state is specified in advance, the first processing may be omitted.

According to example embodiments of the inventive concepts, an analysis method and analysis system capable of calculating a Green's function while reducing the number of quantum gates required for calculation by a quantum processor are provided.

While the inventive concepts have been described with reference to example embodiments thereof, it will be apparent to those of ordinary skill in the art that various changes and modifications may be made thereto without departing from the spirit and scope of the inventive concept as set forth in the following claims.

What is claimed is:

1. An analysis method comprising:
converting, by a classical processor, a Hamiltonian operator of a sub-system corresponding to a basis function and an operator corresponding to an overlapping matrix of the basis function into a spin operator, the basis function representing an N±1 electromagnetic field with respect to an analysis target substance having N electrons, where N represents a natural number;
calculating, by a quantum processor, an expected value of the spin operator;
calculating, by the classical processor, an element of a Hamiltonian matrix corresponding to the Hamilton operator and an element of the overlapping matrix based on the expected value; and
calculating, by the classical processor, a one-electron Green's function, based on the Hamiltonian matrix and the overlapping matrix.

2. The analysis method of claim 1, further comprising:
calculating, by the classical processor, an electronic state of the analysis target substance using the one-electron Green's function.

3. The analysis method of claim 1, wherein the one-electron Green's function is a frequency-based Green's function.

4. The analysis method of claim 1, wherein the basis function is provided by applying a creation operator of an electron and an annihilation operator of the electron to a wave function of a basis state of an N electromagnetic field.

5. The analysis method of claim 4, wherein
a basis function representing the N+1 electromagnetic field is provided by applying the annihilation operator of the electron to the wave function of the basis state of the N electromagnetic field, and
a basis function representing the N−1 electromagnetic field is provided by applying the creation operator to the wave function of the basis state of the N electromagnetic field.

6. The analysis method of claim 4, wherein the wave function of the basis state of the N electromagnetic field is calculated by a Variational Quantum Eigensolver (VQE) method.

7. The analysis method of claim 1, wherein converting the Hamiltonian operator and the operator corresponding to the overlapping matrix of the basis function into the spin operator includes at least one of a Jordan-Wigner transform and a Bravi-Kitaev transform.

8. The analysis method of claim 1, further comprising:
calculating, by the classical processor, an electronic state of the target substance using the one-electron Green's function.

9. An analysis system comprising:
a classical processor configured to
convert a covert a Hamiltonian operator of a sub-system corresponding to a basis function and an operator corresponding to an overlapping matrix of the basis function into a spin operator, the basis function representing an N±1 electromagnetic field with respect to an analysis target substance having N electrons, where N represents a natural number,
calculate an element of a Hamiltonian matrix corresponding to the Hamiltonian operator and an element of the overlapping matrix, based on an expected value of a spin operator, and
calculate a one-electron Green's function, based on the Hamiltonian matrix and the overlapping matrix; and
a quantum processor configured to calculate the expected value of the spin operator.

10. The analysis system of claim 9, wherein the classical processor is configured to calculate an electronic state of the analysis target substance using the one-electron Green's function.

11. The analysis system of claim 9, wherein the classical processor is configured to define the basis function by applying a creation operator and an annihilation operator of an electron to a wave function of a basis state of an N electromagnetic field.

12. The analysis system of claim 11, wherein
a basis function representing the N+1 electromagnetic field is provided by applying the annihilation operator of the electron to the wave function of the basis state of the N electromagnetic field, and
a basis function representing the N−1 electromagnetic field is provided by applying the creation operator to the wave function of the basis state of the N electromagnetic field.

13. The analysis system of claim 11, wherein the analysis system is configured to calculate the wave function, based on a Variational Quantum Eigensolver (VQE) method.

14. The analysis system of claim 9, wherein the classical processor is configured to convert the Hamiltonian operator and the operator corresponding to the overlapping matrix of the basis function into the spin operator by using at least one of a Jordan-Wigner transform and a Bravi-Kitaev transform.

15. The analysis system of claim 9, wherein the classical processor is further configured to calculate an electronic state of the target substance using the one-electron Green's function.

16. The analysis system of claim 15, wherein
the target substance includes quantum logic gates, the quantum logic gates configured to conduct quantum calculations, and
an outcome of the quantum calculations is based on the electronic state of the target substance.
